(19) United States
(12) Patent Application Publication
(10) Pub. No.: US 2015/0001578 A1
(43) Pub. Date: Jan. 1, 2015

(54) POWER SEMICONDUCTOR DEVICE AND METHOD OF MANUFACTURING THE SAME

(71) Applicant: Fairchild Korea Semiconductor Ltd., Bucheon-si (KR)

(72) Inventors: Se-woong OH, Anyang-si (KR); Kyu-hyun LEE, Bucheon-si (KR); Geun-hyoung LEE, Incheon (KR); Sung-min YANG, Goyang-si (KR); Young-chul CHOI, Seoul (KR)

(21) Appl. No.: 14/316,286

(22) Filed: Jun. 26, 2014

Related U.S. Application Data
(60) Provisional application No. 61/840,445, filed on Jun. 27, 2013.

(30) Foreign Application Priority Data
Dec. 23, 2013 (KR) 10-2013-0161777

(51) Int. Cl. H01L 29/739; H01L 29/66; H01L 29/06; H01L 29/10; H01L 29/08; H01L 29/36

(52) U.S. Cl. CPC H01L 29/7397; H01L 29/0821; H01L 29/36; H01L 29/0638; H01L 29/1095; H01L 29/66348
USPC 257/139; 438/138

(57) ABSTRACT

In a general aspect, a power semiconductor device can include a substrate having a first surface and a second surface. The substrate can include at least one uneven portion defined on the second surface. The device can include a gate electrode and an emitter electrode disposed on the first surface of the substrate. A collector region of the device can be defined on at least a part of the at least one uneven portion. The device can also include a buffer layer disposed in the substrate.

### RELATED APPLICATIONS

This application claims priority to and the benefit of U.S. Provisional Patent Application No. 61/840,445, filed on Jun. 27, 2013, in the U.S. Patent Office and Korean Patent Application No. 10-2013-0161777, filed on Dec. 23, 2013, in the Korean Intellectual Property Office, the disclosures of which are incorporated by reference herein in their entireties.

### TECHNICAL FIELD

This disclosure relates to power semiconductor devices and methods of manufacturing the same. More particularly, this disclosure relates to insulated gate bipolar transistors (IGBTs) power semiconductor devices and methods of manufacturing the same.

### BACKGROUND

Recently, an IGBT type power semiconductor device having a high speed switching characteristic of a high power metal-oxide-semiconductor field-effect transistor (MOSFET) and a high power characteristic of a bipolar junction transistor (BJT) has been studied. In the case of a power semiconductor device having a field stop region, impurity ions are implanted into a substrate to define the field stop region. However, high implantation energy is required to implant the impurity ions to a desired depth, and it is difficult to precisely control the depth and/or concentration of the impurity ions implanted in the field stop region.

### SUMMARY

According to a general aspect, a power semiconductor device can include a substrate having a first surface and a second surface. The substrate can have at least one uneven portion defined on the second surface. A gate electrode and an emitter electrode can be disposed on the first surface of the substrate, a collector region can be disposed on at least a part of the at least one uneven portion, and a buffer layer can be defined in the substrate.

Example embodiments can include one or more of the following features. For instance, the at least one uneven portion can include a concave portion recessed from the second surface of the substrate by a predetermined depth. The buffer layer can include a first region that overlaps the concave portion in a perpendicular direction relative to the first surface of the substrate and a second region that does not overlap the concave portion in the perpendicular direction.

The first region of the buffer layer can have a first thickness, and the second region of the buffer layer can have a second thickness that is less than the first thickness. An impurity concentration of the first region of the buffer layer can be greater than an impurity concentration of the second region. The first region of the buffer layer can be separated from the collector region by a first distance in the perpendicular direction and the second region of the buffer layer can be separated from the collector region by a second distance in the perpendicular direction, where the first distance can be less than the second distance.

At least a part of the buffer layer can contact at least a part of the collector region. The collector region can include a p-type impurity and the buffer layer can include an n-type impurity.

The buffer layer can be continuous on a surface parallel to the first surface of the substrate. An impurity concentration of the buffer layer can vary in a perpendicular direction relative to the first surface of the substrate and can vary in a parallel direction relative to the first surface of the substrate. The buffer layer can define a field stop region.

The at least one uneven portion can have a depth in a range of approximately 1 μm to 5 μm from the second surface of the substrate. The at least one uneven portion can include a plurality of concave portions that extend in a parallel direction relative to the first surface of the substrate.

The at least one uneven portion can include a plurality of concave portions separated from each other in a first direction and in a second direction. The first direction can be parallel to the first surface of the substrate, and the second direction can be parallel to the first surface of the substrate and perpendicular to the first direction.

The at least one uneven portion can include a plurality of protrusions separated from each other in a first direction and in a second direction. The first direction can be parallel to the first surface of the substrate, and the second direction can be parallel to the first surface of the substrate and perpendicular to the first direction.

The power semiconductor device can further include a drift region disposed in the substrate and disposed between the buffer layer and the gate electrode. The collector region can be disposed on the entire surface of the at least one uneven portion. The collector region can be disposed on a part of a surface of the at least one uneven portion and not overlap a concave surface of the at least one uneven portion. The buffer layer can be spaced apart from the collector region in a perpendicular direction relative to the first surface of the substrate.

The substrate can include a base region adjacent to the first surface that can include a p-type impurity, and an emitter region disposed in the base region that can include an n-type impurity. The gate electrode can be configured to electrically control a part of the base region adjacent to the emitter region. The emitter electrode can be electrically connected to the base region and the emitter region. The substrate can include a trench recessed from the first surface of the substrate to a predetermined depth and the gate electrode can be disposed in the trench.

In another general aspect, a method of manufacturing a power semiconductor device can include etching a second surface of a substrate including a first surface and the second surface to form at least one uneven portion. The method can also include implanting a first impurity into the second surface of the substrate to define a buffer layer and implanting a second impurity into the second surface of the substrate to define a collector region.

Example embodiments can include one or more of the following features. For instance, forming the buffer layer can includes implanting the first impurity into a concave surface of the at least one uneven portion and annealing the substrate to laterally diffuse the first impurity. Annealing the substrate can include at least one of laser annealing or thermal annealing.

The at least one uneven portion can have a depth in a range of approximately 1 μm to 5 μm from the second surface of the substrate. Forming of the at least one uneven portion can include forming a plurality of concave portions that extend in a first direction parallel to the second surface.

Forming of the at least one uneven portion can include forming a plurality of concave portions separated from each other in a first direction and in a second direction. The first direction can be parallel to the first surface of the substrate, and the second direction can be parallel to the first surface of the substrate and perpendicular to the first direction.

Forming of the at least one uneven portion can include forming a plurality of protrusions separated from each other in a first direction and in a second direction. The first direction can be parallel to the first surface of the substrate, and the second direction can be parallel to the first surface of the substrate and perpendicular to the first direction.

Forming of the collector region can include forming the collector region on at least a part of the at least one uneven portion.

### BRIEF DESCRIPTION OF THE DRAWINGS

These and/or other aspects will become apparent and more readily appreciated from the following description of the embodiments, taken in conjunction with the accompanying drawings in which:

FIG. 1A is a cross-sectional view illustrating a power semiconductor device according to an embodiment.

FIG. 1B is a perspective view illustrating a part of the device of FIG. 1A;

FIGS. 2A TO 2C are graphs illustrating impurity concentration profiles in a buffer layer and a collector region of the power semiconductor device illustrated in FIGS. 1A and 1B;

FIG. 3 is a perspective view illustrating a part of a power semiconductor device according to an embodiment;

FIG. 4 is a perspective view illustrating a part of a power semiconductor device according to an embodiment;

FIG. 5 is a cross-sectional view illustrating a power semiconductor device according to an embodiment;

FIG. 6 is a cross-sectional view illustrating a power semiconductor device according to an embodiment;

FIG. 7 is a cross-sectional view illustrating a power semiconductor device according to an embodiment; and

FIGS. 8A to 8G are cross-sectional views illustrating a method of manufacturing a power semiconductor device according to an embodiment.

### DETAILED DESCRIPTION

Reference will now be made in detail to embodiments, examples of which are illustrated in the accompanying drawings, wherein like reference numerals refer to like elements throughout. In this regard, the embodiments described herein may have different forms and should not be construed as being limited to the descriptions set forth herein.

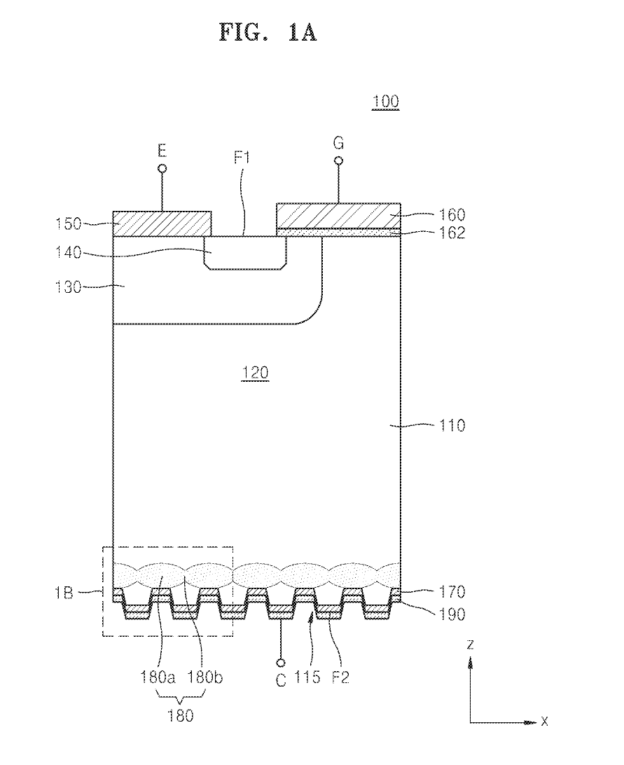

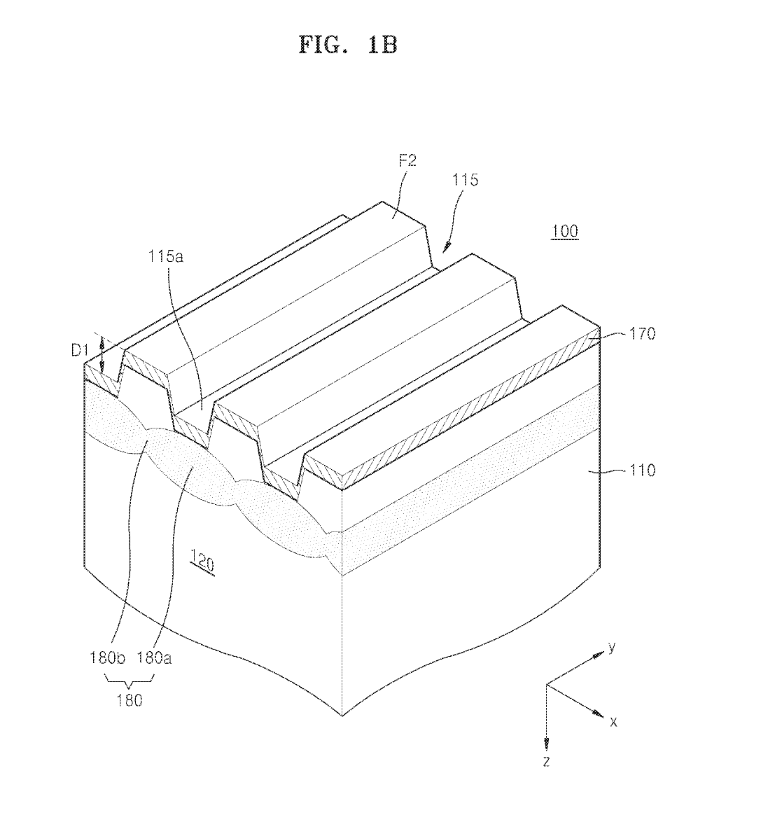

FIG. 1A is a cross-sectional view illustrating a power semiconductor device 100, according to an embodiment. FIG. 1B is a perspective view illustrating a part of the device of FIG. 1A. Specifically, FIG. 1B is a perspective view illustrating the device of FIG. 1A as seen from a bottom of the device.

Referring to FIGS. 1A and 1B, the power semiconductor device 100 may include a substrate 110, a drift region 120, a base region 130, an emitter region 140, an emitter electrode 150, a gate electrode 160, a collector region 170, and a buffer layer 180.

The substrate 110 may include a silicon substrate, a germanium substrate, a silicon-germanium substrate, or a semiconductor substrate having a wide bandgap, such as a silicon carbide substrate, a gallium nitride substrate, or a diamond substrate, or the like. The substrate 110 may include a first surface F1 and a second surface F2. At least one uneven portion 115 may be formed (defined) on the second surface F2 of the substrate 110. At least one uneven portion 115 may include at least one concave portion 115a recessed from the second surface F2 to a first depth D1. Here, the at least one concave portion 115a refers to a portion of the device 100 including a bottom surface recessed from the second surface F2. In certain embodiments, the at least one concave portion 115a may be in the form of a line that extends in one direction (e.g., the y direction of FIG. 1B) parallel to the second surface F2 of the substrate 110 (or parallel to the first surface F1 of the substrate 110). The first depth D1 of the at least one uneven portion 115 may vary according to a depth at which the buffer layer 180 of the power semiconductor device 100 is formed. In one embodiment, the first depth D1 may be in a range of approximately 1 μm to 5 μm, but is not limited thereto.

The drift region 120, having a predetermined depth from the first surface F1 of the substrate 110, may be disposed in the substrate 110. The drift region 120 may be an impurity (e.g., implant or diffusion) region doped with a first impurity. The first impurity may be an n-type impurity such as phosphorous (P), arsenic (As), antimony (Sb), etc. The drift region 120 may be an impurity (e.g., implant or diffusion) region doped at a low concentration and may have impurity concentration of, for example, no more than 1E14 cm⁻³. A depth of the drift region 120 may be appropriately selected in accordance with a desired breakdown voltage of the power semiconductor device 100. For example, when a breakdown voltage of about 600V is desired, the drift region 120 may be formed (disposed) to a depth of about 60 μm. However, the depth of the drift region 120 is not limited thereto. In certain embodiments, the drift region 120 may be formed (disposed) in a silicon layer epitaxially grown on the substrate 110. The drift region 120 may be a portion of the substrate 110 that is doped with the n-type impurity.

Although not shown, an impurity concentration profile of the drift region 120 may vary in a direction (e.g., the z direction of FIG. 1A) perpendicular to the first surface F1 of the substrate 110. For example, when the drift region 120 is formed by an epitaxial growth process, the impurity concentration profile may vary with a kind of an impurity ion used, an ion implantation energy, and a diffusion time of a process used for forming the drift region 120.

The base region 130 and the emitter region 140 may be formed (disposed) on the drift region 120, so as to be adjacent to the first surface F1 of the substrate 110. The base region 130 may be an impurity (e.g., implant or diffusion) region doped with a second impurity. The second impurity may be a p-type impurity such as aluminum (Al), boron (B), indium (In), potassium (K), etc. The base region 130 may form a p-n junction region with the drift region 120. Although not shown, the base region 130 may include a first base region (P++ region) formed at an upper side and a second base region (P− region) formed under the first base region P++ in accordance with doping concentration of the impurity. The first base region (P++ region) may have an impurity (doping) concentration of about 1E19 cm⁻³ and the second base region (P− region) may have an impurity (doping) concentration of about 1E17 cm⁻³.

The emitter region 140 may be formed (disposed) in the base region 130, so as to be adjacent to the first surface F1 of the substrate 110. The emitter region 140 may be an impurity (e.g., implant or diffusion) region doped with a third impurity at high concentration. In certain embodiments, the third impurity may be an n-type impurity such as P, As, Sb, etc. The emitter region 140 may have impurity concentration in a range of approximately 1E18 cm⁻³ to 1E20 cm⁻³.

The emitter electrode 150 may be formed (disposed) on the base region 130 and the emitter region 140. The gate electrode 160 may be formed (disposed) on the drift region 120, the base region 130, and the emitter region 140 and a gate insulation layer 162 may be interposed (disposed) between the gate electrode 160 and the drift region 120, the base region 130, and the emitter region 140. The gate electrode 160 may define a channel in the base region 130 that is positioned between the drift region 120 and the emitter region 140 by applying a voltage to the gate electrode 160.

Although not shown, an insulating layer or a passivation layer that covers the emitter electrode 150 and the gate electrode 160 may be further formed.

The collector region 170 may be formed (defined) to have a predetermined depth along the at least one uneven portion 115 formed on the second surface F2 of the substrate 110. The collector region 170 may be an impurity (e.g., implant or diffusion) region doped with a fourth impurity. The fourth impurity may be a p-type impurity such as Al, B, In, K, etc. An impurity doping concentration of the collector region 170 may be, for example, in a range of approximately 1E17 cm⁻³ to 1E19 cm⁻³. The collector region 170 may have a thickness of no more than 1 μm.

As illustrated in FIG. 1B, the collector region 170 may be formed (disposed) conformally along an inner wall and the second surface F2 of the at least one concave portion 115a. In an embodiment, a side wall of the at least one concave portion 115a may be inclined to have a predetermined slope and the collector region 170 may be formed on the side wall of the at least one concave portion 115a to an approximate thickness of the less than 1 μm.

The buffer layer 180 may be formed (defined) between the drift region 120 and the collector region 170. The buffer layer 180 may be an impurity (e.g., implant or diffusion) region doped with a fifth impurity. The fifth impurity may be an n-type impurity such as P, As, Sb, etc. In addition, the fifth impurity may be an n-type impurity such as selenium (Se), sulfur (S), titanium (Ti), bismuth (Bi), etc. The buffer layer 180 may function as a barrier for preventing holes from moving from the p-type collector region 170 to the drift region 120. The buffer layer 180 may be doped with an n-type impurity of a concentration at which a field stop region is defined, that is, sufficient to prevent a depletion region from extending to the collector region 170 formed on a surface of the substrate 110 opposite to the drift region 120. For example, the concentration of the impurity included in the buffer layer 180 may be, for example, in a range of approximately 1E17 cm⁻³ to 1E19 cm⁻³.

In some embodiments, the buffer layer 180 may be formed to extend in a first direction and a second direction (e.g., the x and y directions of FIG. 1B) parallel to the second surface F2 of the substrate 110 (and also parallel to the first surface F1 of the substrate 110). The buffer layer 180 may include a first region 180a that overlaps the at least one concave portion 115a in a perpendicular direction and a second region 180b that does not overlap the at least one concave portion 115a in the perpendicular direction. Here, overlapping in the perpendicular direction may be understood that positions in an x-y plane (e.g., positions of projections to the x-y plane) are the same. In certain embodiments, concentration of a doping impurity in the first region 180a of the buffer layer 180 may be substantially higher than that of a doping impurity concentration in the second region 180b of the buffer layer 180. The first region 180a of the buffer layer 180 may have a first thickness in the perpendicular direction, and the second region 180b of the buffer layer 180 may have a second thickness in the perpendicular direction, the second thickness being less than the first thickness.

A first distance between the first region 180a of the buffer layer 180 and the collector region 170 in the perpendicular direction (e.g., the z direction of FIG. 1B) may be less than a second distance between the second region 180b of the buffer layer 180 and the collector region 170 in the perpendicular direction. The first distance may be in a range of approximately 0 μm to 5 μm. In this example, the first distance and the second distance may refer to distances from a lowermost part of the buffer layer 180 to an uppermost part of the collector region 170. As illustrated in FIG. 1A, when the first region 180a of the buffer layer 180 contacts, or is very close to, the collector region 170, the first distance may be 0 μm. Unlike in the above example, the first region 180a of the buffer layer 180 may be separated from the collector region 170 by a predetermined distance. In this case, the first distance may be no more than 5 μm.

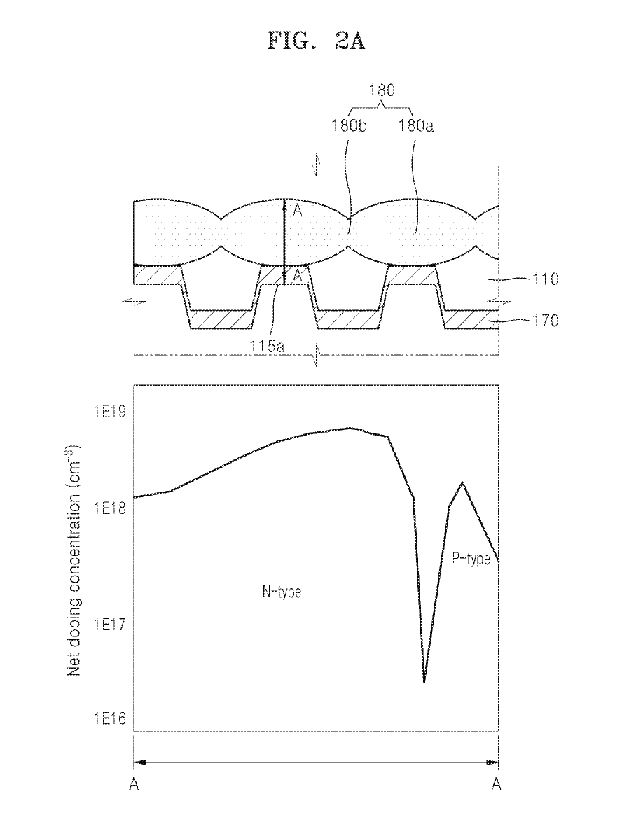

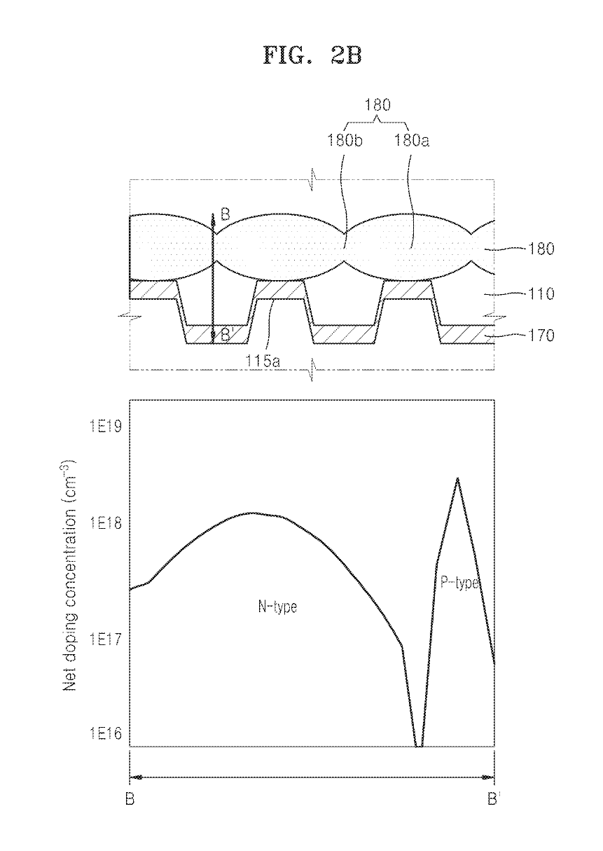

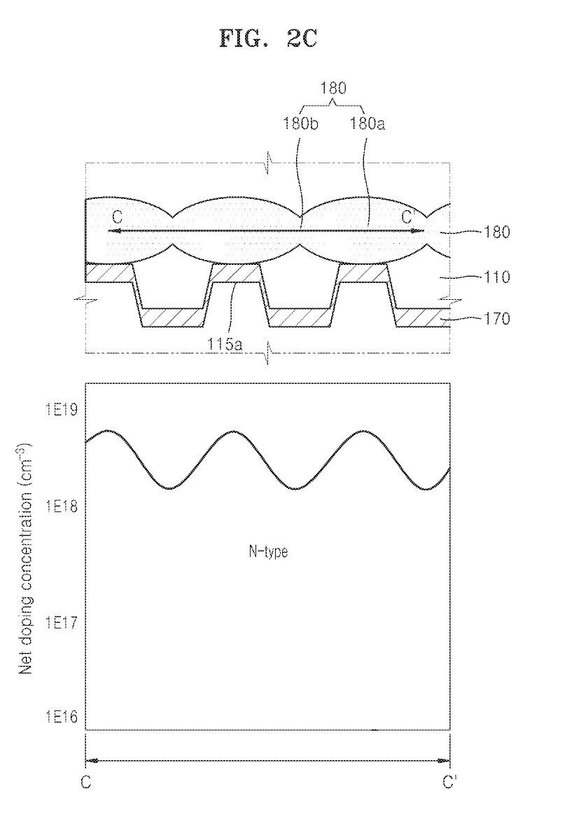

The buffer layer 180 may be formed (defined) by implanting impurity ions into the at least one concave portion 115a and laterally diffusing the impurity ions by an annealing process. Therefore, a position of the buffer layer 180 (that is, a distance from the second surface F2 of the substrate 110 to the buffer layer 180) may be controlled by controlling the first depth D1 of the at least one concave portion 115a. Further, the impurity doping concentration of the buffer layer 180 may be controlled by forming the buffer layer 180 using an ion implantation process. In addition, the second region 180b of the buffer layer 180 can be doped with an n-type impurity of a low concentration to serve as a hole source region for supplying holes from the collector region 170. An example doping concentration profile for the buffer layer 180 will be described in further detail below with reference to FIGS. 2A to 2C.

A collector electrode 190 may be formed (disposed) on the second surface F2 of the substrate 110. The collector electrode 190 may be conformally formed in accordance with a profile of the uneven portion 115 and may be formed to cover the collector region 170. The collector electrode 190 may be used to provide current to the collector region 170.

Operation the power semiconductor device 100 will now be briefly described.

When a positive voltage is applied to the gate electrode 160, a part of the p-type base region 130, positioned between the n-type emitter region 140 and the n-type drift region 120 and adjacent to the gate electrode 160, is inverted to be n-type so that a channel is formed and electrons may be injected from the n-type emitter region 140 into the n-type drift region 120. Accordingly, a forward current may then flow through the power semiconductor device 100. When a gate voltage Vg which is greater than a threshold voltage Vth is applied to the gate electrode 160 (Vg>Vth), and a collector voltage Vc which is greater than a forward-bias voltage Vfb is applied to the collector electrode 190 (Vc>Vfb) (a forward-bias voltage Vfb is defined as a voltage at which a p-n junction between the p-type collector region 170 and the n-type buffer layer 180 is forward-biased), holes may be injected from the collector electrode 190 into the n-type drift region 120 with the p-type collector region 170 interposed therebetween. Thus, conductivity modulation may occur and a resistance of the drift region 120 may be reduced.

In the case where a negative voltage is applied to the gate electrode 160, when a predetermined voltage (an emitter voltage<the collector voltage) is applied to the emitter electrode 150 and the collector electrode 190, the depletion region may be diffused from the p-type base region 130 into the n-type drift region 120. Therefore, the power semiconductor device 100 may maintain a high electric field.

In some embodiments, the buffer layer 180 of the power semiconductor device 100 may be formed by implanting ions into the at least one concave portion 115a and laterally diffusing the implanted ions to precisely control the position, thickness, and/or impurity concentration of the buffer layer 180. Thus, the breakdown voltage of the power semiconductor device 100 may be improved or increased, and conduction loss and/or switching loss may be reduced. Accordingly, the power semiconductor device 100 may have improved electrical characteristics as compared to current IGBT implementations.

FIGS. 2A to 2C are graphs illustrating example impurity concentration profiles of the buffer layer 180 and the collector region 170 of the power semiconductor device 100 of FIGS. 1A and 1B.

In particular, FIG. 2A illustrates an impurity concentration profile of the first region 180a of the buffer layer 180 in a perpendicular direction, FIG. 2B illustrates an impurity concentration profile of the second region 180b of the buffer layer 180 in the perpendicular direction, and FIG. 2C illustrates the impurity concentration profile of the buffer layer 180 in a horizontal direction. The impurity concentration profiles described with reference to FIGS. 2A to 2C were obtained from a computer simulation. Distances and doping densities illustrated in FIGS. 2A to 2C are given by way of example and the doping densities and distances are not limited thereto.

Referring to FIG. 2A, the first region 180a of the buffer layer 180, the part of the buffer layer 180 that overlaps the concave portion 115a in the perpendicular direction, may include an n-type impurity of the concentration in a range of approximately 1E17 cm⁻³ to 1E19 cm⁻³. The buffer layer 180 may have a uniform n-type impurity concentration profile over the first region 180a along the line A-A′ of FIG. 2A. The buffer layer 180 may have an n-type impurity profile doped at a high concentration, e.g., up to 4E18 cm⁻³. The collector region 170 may be formed (disposed) under the first region 180a and may be doped with a p-type impurity with a concentration in a range of approximately 1E17 cm⁻³ to 1E19 cm⁻³.

A distance (first distance) between the first region 180a of the buffer layer 180 and the collector region 170 in the perpendicular direction (with respect to the first surface F1 of the substrate) 110) may be smaller than a distance (second distance) between the second region 180b of the buffer layer 180 and the collector region 170 in the perpendicular direction. Although the first distance may be small (e.g., ranging from several nanometers to several hundred nanometers), the p-n junction region may be formed between the buffer layer 180 including the n-type impurity and the collector region 170 including the p-type impurity.

Referring to FIG. 2B, the second region 180b of the buffer layer 180, that is, the part of the buffer layer 180 that does not overlap the concave portion 115a in the perpendicular direction, may include an n-type impurity with a concentration in a range of approximately 1E17 cm⁻³ to 1E19 cm⁻³. The collector region 170 may be formed (disposed) under the second region 180b and may be doped with a p-type impurity with a concentration in a range of approximately 1E17 cm⁻³ to 1E19 cm⁻³.

The second distance between the second region 180b of the buffer layer 180 and the collector region 170 may be larger than the first distance between the first region 180a of the buffer layer 180 and the collector region 170, as indicated herein. The second distance may correspond to a depth from the second surface F2 of the substrate 110 to the buffer layer 180. For example, the depth from the second surface F2 of the substrate 110 to the buffer layer 180 may vary with the breakdown voltage of the power semiconductor device 100, the thickness and/or impurity concentration of the collector region 170, and/or the thickness or impurity concentration of the buffer layer 180.

In comparison with FIG. 2A, a portion of the substrate 110 between the second region 180b of the buffer layer 180 and the collector region 170, which is illustrated along the line B-B′ of FIG. 2B, may have an n-type impurity concentration lower than that of the second region 180b. The portion of the substrate 110 between the second region 180b and the collector region 170 may serve as a hole supplying path (source) that may provide holes to the drift region 120. Therefore, hole mobility of the power semiconductor device 100 may be increased and an on-state resistance (i.e., a resistance when a device is turned on) may be reduced.

Referring to FIG. 2C, an n-type impurity may be used to dope the entire region of the buffer layer 180. The first region 180a may have impurity concentration greater than that of the second region 180b. In FIG. 2C, a plurality of concave portions 115a are formed to be separated from each other in one direction and, in the buffer layer 180, the impurity doping concentration is repeatedly increased and reduced in the direction along which the plurality of concave portions 115a are separated from each other. Since the n-type impurity implanted into the first region 180a may be laterally diffused into the second region 180b by an annealing process, the impurity concentration of the second region 180b may be substantially smaller than an impurity concentration of the first region 180a. However, the second region 180b may have an impurity concentration sufficient to serve as the buffer layer 180.

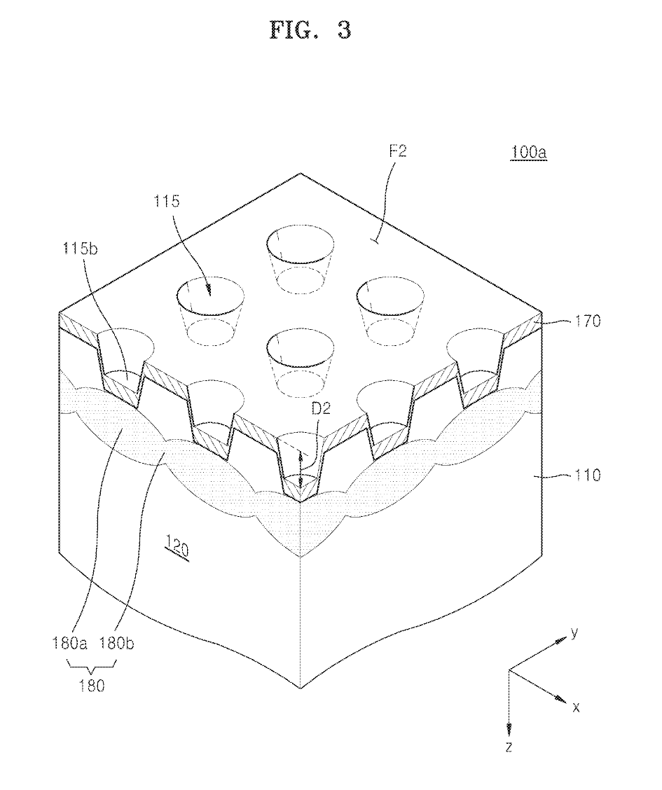

FIG. 3 is a perspective view illustrating a part of a power semiconductor device 100a, according to an embodiment. The power semiconductor device 100a is similar to the power semiconductor device 100 described with reference to FIGS. 1A and 1B, except for the shape of an at least one uneven portion 115. Accordingly, the following discussion of the power semiconductor device 100a will be limited to describing this aspect of the device 100a and its relationship to the other elements of the device 100a.

Referring to FIG. 3, the at least one uneven portion 115 has a second depth D2 from the second surface F2 of the substrate 110 and may include a plurality of concave portions 115b separated from each other in a first direction and a second direction (e.g., x and y directions of FIG. 3), which are both parallel to the second surface F2 of the substrate 110 (and parallel to a first surface F1 (not shown)).

In some embodiments, horizontal cross-sections of the concave portions 115b may be circular, square, polygonal, elliptical, etc. However, the horizontal cross-sections of the concave portions 115b are not limited to the above shapes. A width of the concave portions 115b and a distance between adjacent concave portions 115b may be in a range of approximately 1 μm to 10 μm. However, the width of the concave portions 115b and the distance between the concave portions 115b are not limited to the above range of widths. Since impurity ions implanted through the concave portions 115b may be laterally diffused to form the buffer layer 180 that extends in the x and y directions, the width of the concave portions 115b and the distance between the concave portions 115b may be selected based on consideration of a minimum impurity concentration of the buffer layer 180.

In certain embodiments, the second depth D2 of the concave portions 115b may be in a range of approximately 1 μm to 5 μm. However, the second depth D2 of the concave portions 115b is not limited to the above range of depths. The second depth D2 of the concave portions 115b may be selected based on consideration of a position of the buffer layer 180.

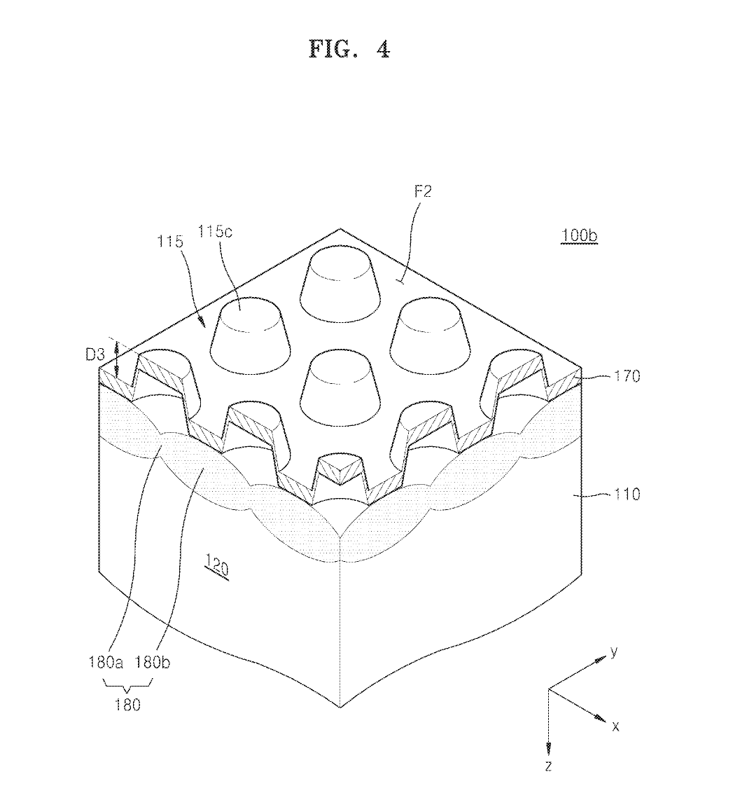

FIG. 4 is a perspective view illustrating a part of a power semiconductor device 100b, according to an embodiment. The power semiconductor device 100b is similar to the power semiconductor device 100 described with reference to FIGS. 1A and 1B, except for a shape of an at least one uneven portion 115. Accordingly, the following discussion of the power semiconductor device 100b will be limited to describing this aspect of the device 100b and its relationship to the other elements of the device 100b.

Referring to FIG. 4, the at least one uneven portion 115 has a first depth D3 from the second surface F2 of the substrate 110 and may include a plurality of protrusions 115c separated from each other in a first direction and a second direction (e.g., x and y directions of FIG. 4), which are both parallel to the second surface F2 of the substrate 110 (and parallel to a first surface F1 (not shown)).

In some embodiments, horizontal cross-sections of the protrusions 115c may be circular, square, polygonal, elliptical, etc. However, the horizontal cross-sections of the protrusions 115c are not limited to the above shapes. A width of the protrusions 115c and a distance between adjacent protrusions 115c may be in a range of approximately 1 μm to 10 μm. However, the width of the protrusions 115c and the distance between the protrusions 115c are not limited to the above range of widths. Since impurity ions implanted through the part of the substrate 110 that does not overlap the protrusions 115c in a perpendicular direction, that is, the second surface F2 of the substrate 110 may be laterally diffused to form the buffer layer 180 that extends in the x and y directions, the width of the protrusions 115c and the distance between the protrusions 115c may be selected based on consideration of a minimum impurity concentration of the buffer layer 180.

In certain embodiments, the first depth D3 of the protrusions 115c may be in a range of approximately 1 μm to 5 μm. However, the first depth D3 of the protrusions 115c is not limited to the above range of depths. The first depth D3 of the protrusions 115c may be selected on consideration of a position of the buffer layer 180.

The buffer layer 180 may include the first region 180a that overlaps the protrusions 115c in the perpendicular direction and the second region 180b that does not overlap the protrusions 115c in the perpendicular direction. An impurity doping concentration of the first region 180a of the buffer layer 180 may be substantially less than an impurity doping concentration of the second region 180b. A distance between the first region 180a and the collector region 170 in the perpendicular direction (relative to the surface F2 of the substrate 110) may be larger than a distance between the second region 180b and the collector region 170.

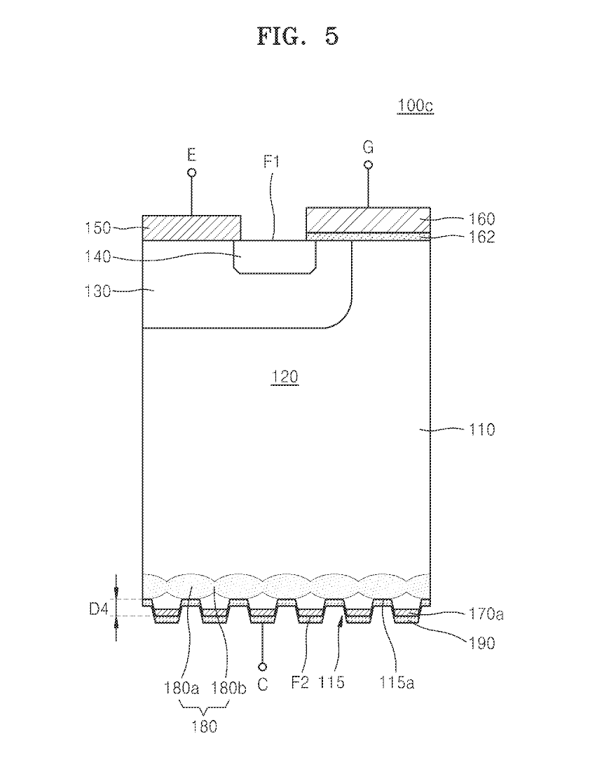

FIG. 5 is a cross-sectional view illustrating a power semiconductor device 100c, according to an embodiment. The power semiconductor device 100c is similar to the power semiconductor device 100 described with reference to FIGS. 1A and 1B, except for a structure of a collector region 170a. Accordingly, the following discussion of the power semiconductor device 100c will be limited to describing this aspect of the device 100c and its relationship to the other elements of the device 100c

Referring to FIG. 5, at least one uneven portion 115 may be formed on the second surface F2 of the substrate 110. For example, the at least one uneven portion 115 may include at least one concave portion 115a recessed from the second surface F2 of the substrate 110 by a depth D4.

The collector region 170a may be formed to have (disposed at) a predetermined depth from the second surface F2 of the substrate 110 and may not be formed (disposed) on the at least one concave portion 115a. Therefore, the collector region 170a may not be formed (disposed) under the first region 180a of the buffer layer 180 and may be formed (disposed) under the second region 180b of the buffer layer 180.

The collector electrode 190 may be conformally formed (disposed) on the second surface F2 of the substrate 110 along the at least one uneven portion 115. The collector electrode 190 may be formed (disposed), so as to be adjacent to the first region 180a of the buffer layer 180.

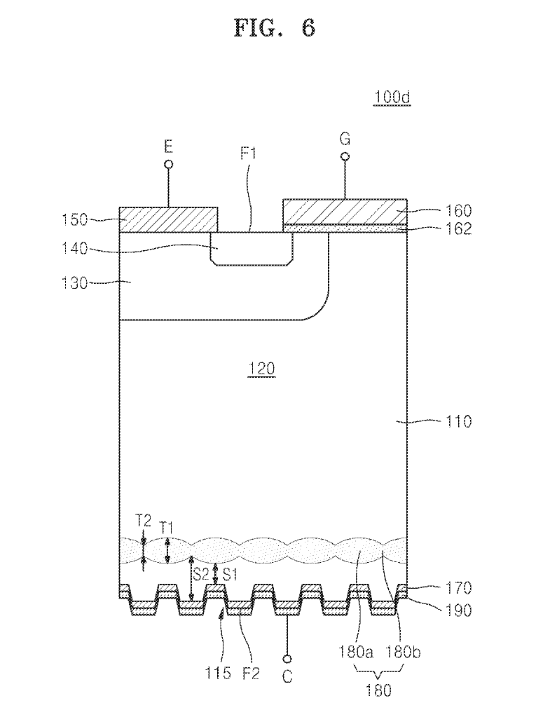

FIG. 6 is a cross-sectional view illustrating a part of a power semiconductor device 100d, according to an embodiment. The power semiconductor device 100d is similar to the power semiconductor device 100 described with reference to FIGS. 1A and 1B, except for the position of the buffer layer 180. Accordingly, the following discussion of the power semiconductor device 100d will be limited to describing this aspect of the device 110d and its relationship to the other elements of the device 110d.

Referring to FIG. 6, the buffer layer 180 may be separated from the collector region 170 in a direction perpendicular to the second surface F2 of the substrate 110 (and perpendicular to the first surface F1 of the substrate 110). The buffer layer 180 may include the first region 180a that overlaps the at least one concave portion 115a in the perpendicular direction and the second region 180b that does not overlap the at least one concave portion 115a in the perpendicular direction. In exemplary embodiments, a first distance 51 between the first region 180a of the buffer layer 180 and the collector region 170 in the perpendicular direction may be smaller than a second distance S2 between the second region 180b of the buffer layer 180 and the collector region 170 in the perpendicular direction. The first distance S1 may have a value greater than 0, so that the buffer layer 180 does not contact the uppermost part of the collector region 170 and may be separated from the collector region 170 in the perpendicular direction. For example, the first distance S1 may be 5 μm or less, but is not limited thereto.

The buffer layer 180 may be implemented by implanting impurity ions into the at least one concave portion 115a and by laterally diffusing the implanted impurity ions by an annealing process. In this case, the first distance S1 between the buffer layer 180 and the collector region 170 may be controlled by controlling energy and dose of an impurity ion implantation process.

A first thickness T1 of the first region 180a of the buffer layer 180 in the perpendicular direction may be larger than a second thickness T2 of the second region 180b of the buffer layer 180 in the perpendicular direction.

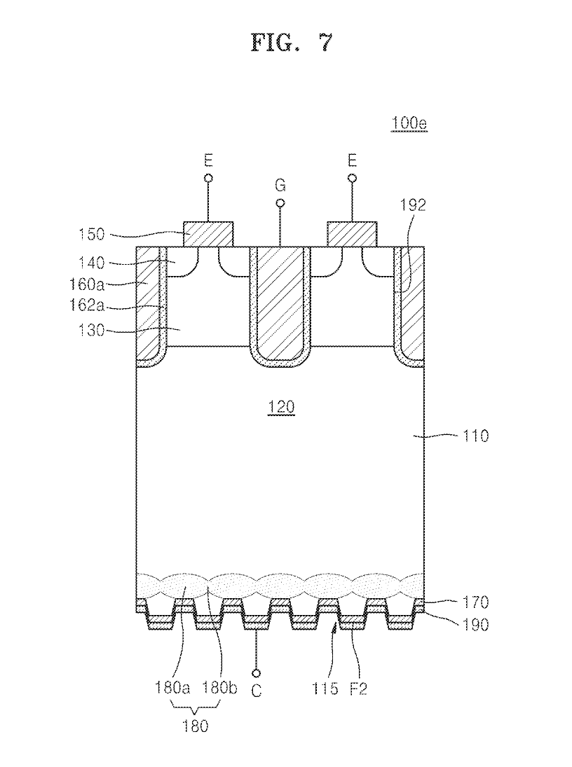

FIG. 7 is a cross-sectional view illustrating a part of a power semiconductor device 100e, according to an embodiment. The power semiconductor device 100e may be a trench gate type power semiconductor device that is similar to the power semiconductor device 100 described with reference to FIGS. 1A and 1B, except for a structure of a gate electrode 160a. Accordingly, the following discussion of the power semiconductor device 100e will be limited to describing this aspect of the device 110e and its relationship to the other elements of the device 110e.

Referring to FIG. 7, trenches 192 having a predetermined depth from the first surface F1 of the substrate 110 may be formed. Gate insulation layers 162a may be conformally formed in the trenches 192, and the gate electrodes 160a may be formed on the gate insulation layers 162a to fill the trenches 192.

Bottoms of the trenches 192 can be rounded and bottoms of the gate electrodes 162a that fill the trenches 192 may be also rounded. Therefore, breakdown of the gate insulation layers 162a, due to concentration of an electric field that may occur at edges of the gate electrodes 160a, may be avoided.

The bottoms of the trenches 192 may be formed at a level lower than that of an uppermost surface of the drift region 120. Therefore, a bottom surface of the base region 130 may be formed at a level higher than that of the bottoms of the trenches 192.

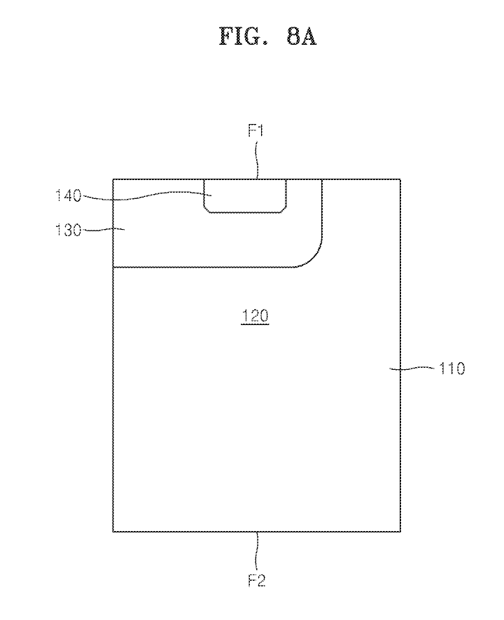

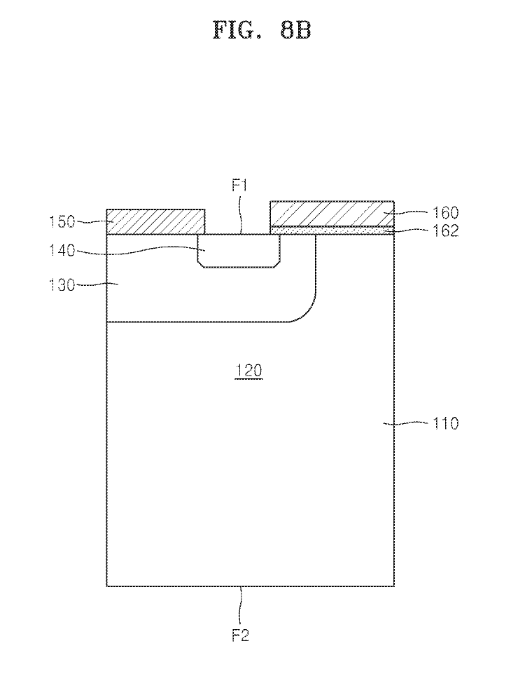

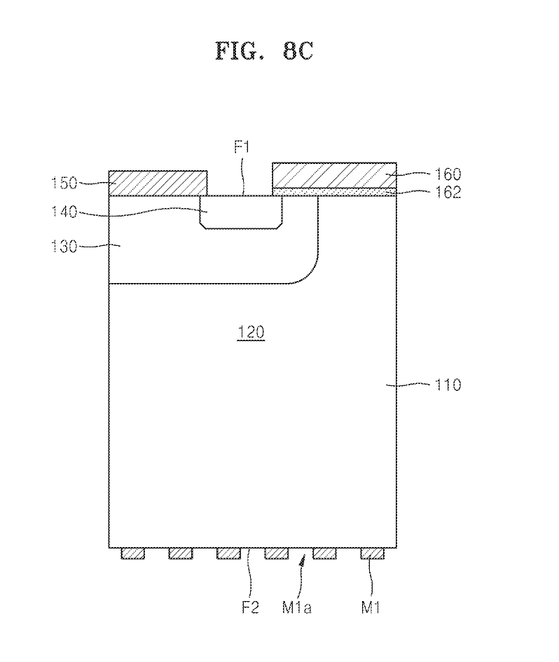

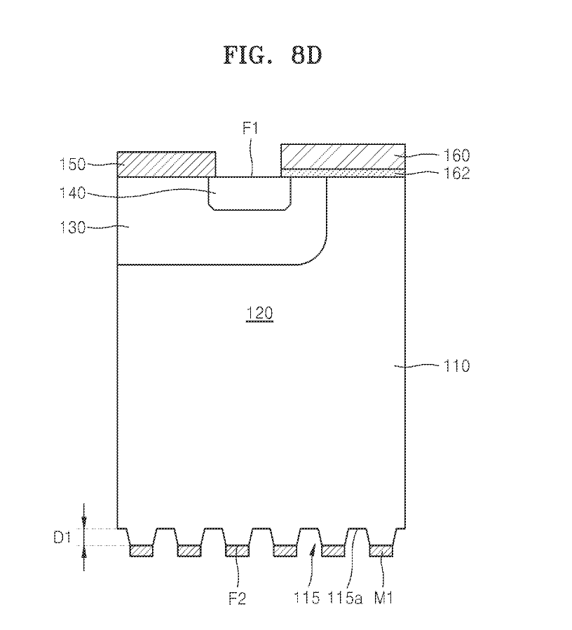

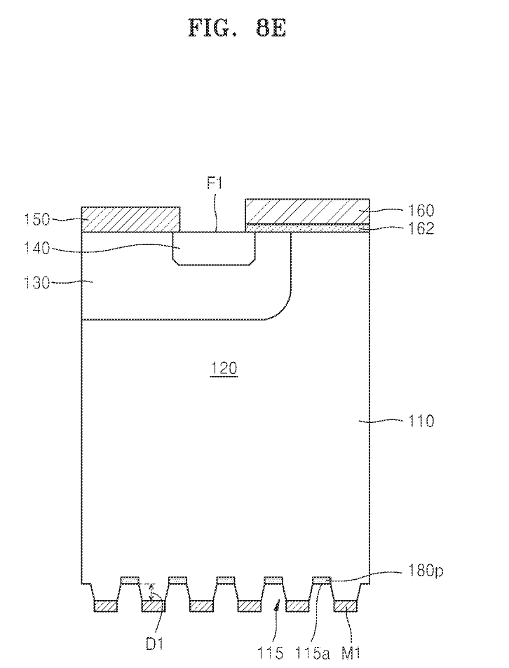

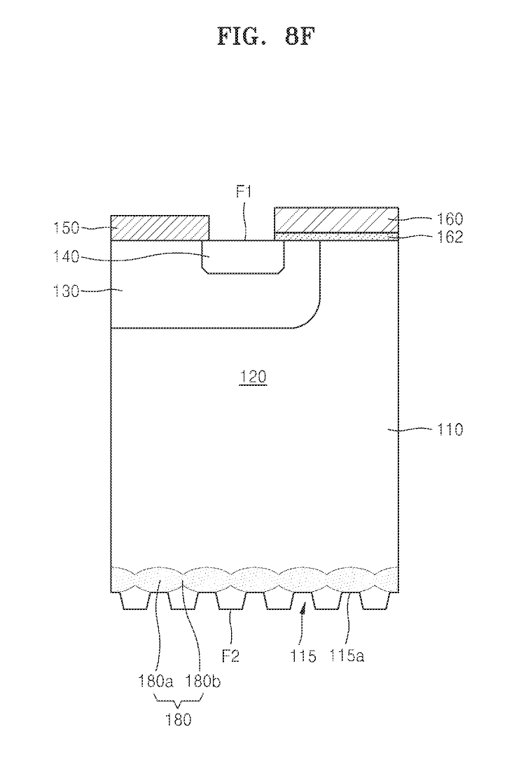

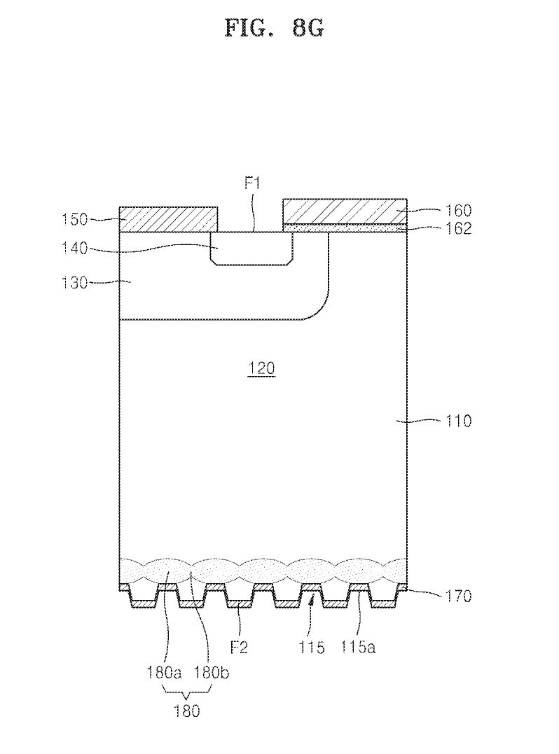

FIGS. 8A to 8G are cross-sectional views illustrating a method of manufacturing a power semiconductor device, according to an embodiment. The manufacturing method may be, for example, a method of manufacturing the power semiconductor device 100 described with reference to FIGS. 1A and 1B.

Referring to FIG. 8A, a substrate 110 including a first surface F1 and a second surface F2 is provided.

The substrate 110 may be a silicon substrate, a germanium substrate, a silicon-germanium substrate, or a semiconductor substrate having a wide bandgap such as a silicon carbide substrate, a gallium nitride substrate, or a diamond substrate, or the likes. The substrate 110 may be a substrate manufactured by a float zone (FZ) method, a substrate manufactured by a Czochralski (CZ) method, or an epitaxial substrate grown on a template substrate (not shown) by an epitaxial growth process.

The substrate 110 may be doped with an n-type impurity such as P, As, Sb, etc. at a predetermined concentration. The substrate 110 may have an n-type impurity concentration of no more than 1E14 cm⁻³. For example, when the substrate 110 is a CZ substrate or an FZ substrate, the entire region of the substrate 110 may include n-type impurity of a uniform concentration. In comparison, when the substrate 110 is an epitaxial substrate, the n-type impurity may be in-situ doped during an epitaxial process used to form the substrate 110. In such embodiments, an n-type impurity may be doped on the substrate 110 to have a uniform concentration through the total height of the substrate 110, or may be doped to have a specific concentration profile in accordance with a height of the substrate 110.

A p-type impurity can be ion implanted into the first surface F1 of the substrate 110 so that a base region 130 having a predetermined depth from the first surface F1 may be formed in a uniform region of the substrate 110.

In a process of forming the base region 130, after a first mask (not shown) is formed on the first surface F1 of the substrate 110, a p-type impurity may be implanted into the substrate 110 to a predetermined depth using the first mask as an ion implantation mask. The p-type impurity may include Al, B, In, K, etc., and have a doping concentration in a range of approximately 1E16 cm⁻³ to 1E19 cm⁻³.

Although not shown, a first base region (P++ region) may be formed (disposed) on an upper side and a second base region (P− region) may be formed (disposed) under the first base region P++ by varying the doping concentration of the p-type impurity with which the base region 130 is doped. The first base region (P++ region) may have an impurity concentration of approximately 1E19 cm⁻³ and the second base region (P− region) may have impurity concentration of approximately 1E17 cm⁻³.

A portion of the substrate 110 under the base region 130 may be defined as a drift region 120. Accordingly, the concentration of the n-type impurity with which the substrate 110 is doped may be the impurity concentration of the drift region 120 that is defined in the substrate 110.

After a second mask (not shown) that exposes a portion of the substrate 110 corresponding with the base region 130 is formed, an n-type impurity is implanted into the base region 130 to a predetermined depth using the second mask as an ion implantation mask, so that an emitter region 140 may be formed. In exemplary embodiments, a depth (that is, a distance from the first surface F1 of the substrate 110 to a bottom surface of the emitter region 140) of the emitter region 140 may be smaller than a depth of the base region 130. In some embodiments, the entire bottom surface of the emitter region 140 may be positioned in the base region 130.

The n-type impurity of the emitter region 140 may include P, As, Sb, etc. and the doping concentration of the n-type impurity may be in a range of approximately 1E18 cm⁻³ to 1E20 cm⁻³.

Referring to FIG. 8B, a gate insulation layer 162 and a gate electrode 160 may be sequentially formed on the first surface F1 of the substrate 110 to overlap the emitter region 140, the base region 130, and the drift region 120.

The gate insulation layer 162 may be formed of a silicon oxide, a silicon nitride, or a high-k dielectric material (i.e., a dielectric material having a high dielectric constant), or mixtures thereof by a chemical vapor deposition (CVD) process, a physical vapor deposition (PVD) process, or the like.

The gate electrode 160 may be formed of polysilicon doped with an impurity, a metal, or a metal nitride, or mixtures thereof. Although not shown, the gate electrode 160 may further include an ohmic contact layer.

An emitter electrode 150 may then be formed on the first surface F1 of the substrate 110. The emitter electrode 150 may be formed to be separated from the gate electrode 160 and to overlap the emitter region 140 and the base region 130. Therefore, the gate electrode 160 may be arranged on a part of the emitter region 140 and the emitter electrode 150, which is not electrically connected to the gate electrode 160, may be arranged on the part of the emitter region 140.

In other embodiments, unlike as described with reference to FIGS. 8A and 8B, after the gate electrode 160 is formed on the first surface F1 of the substrate 110, a p-type impurity may be implanted into the substrate 110 using the gate electrode 160 as an ion implantation mask so that the base region 130 may be defined. After the emitter electrode 150 is formed on the first surface F1 of the substrate 110, an n-type impurity can be implanted into the base region 130 using the emitter electrode 150 and the gate electrode 160 as ion implantation masks so that the emitter region 140 may be defined. A thermal process may be selectively further performed after the impurity implantation processes. In such a case, the base region 130 and the emitter region 140 may be formed by a self-aligned method, so that misalignment between the gate electrode 160 and the base region 130, between the gate electrode 160 and the emitter region 140, and/or between the emitter electrode 150 and the emitter region 140 may be prevented.

Referring to FIG. 8C, a third mask M1 may be formed on the second surface F2 of the substrate 110. The third mask M1 may be a photoresist mask or a hard mask. The third mask M1 may include at least one opening M1a. The at least one opening M1a may be formed to have a shape corresponding to that of an uneven portion (115 of FIG. 8D) to be formed in a subsequent process. For example, when the uneven portion 115 includes a line-shaped concave portion (115a of FIG. 1A) as illustrated in FIG. 1A, the at least one opening M1a may be in the form of a line that extends in a first direction parallel to the second surface F2 of the substrate 110 (and parallel to the first surface F1 of the substrate 110). In comparison to the above, when the uneven portion 115 includes a plurality of concave portions (115b of FIG. 3) separated from each other in the first direction and the second direction, x and y directions as illustrated in FIG. 3, the at least one opening M1a may be a plurality of openings M1a separated from each other in the first direction and the second direction on the substrate 110. When the uneven portion 115 includes a plurality of protrusions (115c of FIG. 4) as illustrated in FIG. 4, the third mask M1 can be formed to include a plurality of islands (not shown) corresponding to positions in which the protrusions 115c are formed and the openings M1a may be used to define spaces among (between) the plurality of islands.

Referring to FIG. 8D, the second surface F2 of the substrate 110 may be etched using the third mask M1 as an etching mask so that at least one uneven portion 115 having a first depth D1 from the second surface F2 of the substrate 110 may be formed (defined).

The at least one uneven portion 115 may be at least one concave portion 115a in the form of a line that extends in the first direction. As illustrated in FIG. 8D, the at least one uneven portion 115 may be formed to have a sidewall having a slope that is predetermined by the etching process used. The at least one uneven portion 115 may have a sidewall perpendicular to the second surface F2 of the substrate 110 (and perpendicular to the first surface F1 of the substrate 110).

The at least one concave portion 115a may have the first depth D1 in a range of approximately 1 μm to 5 μm. However, the first depth D1 is not limited to the above range of depths. The first depth D1 may vary with a thickness of a buffer layer (180 of FIG. 8F) that is to be formed in a subsequent process, a position of the buffer layer 180, concentration of an impurity to be implanted into the buffer layer 180, a thickness of a collector region (170 of FIG. 8G), and concentration of an impurity to be implanted into the collector region 170.

Referring to FIG. 8E, an n-type impurity can be implanted into the at least one concave portion 115a so that a preliminary buffer layer 180p may be formed (defined). The n-type impurity is not implanted into the second surface F2 of the substrate 110 covered with the third mask M1 so that the preliminary buffer layer 180p may be formed only on the at least one concave portion 115a, that is, in the part of the substrate 110 that overlaps the at least one concave portion 115a in the perpendicular direction, as described herein.

Impurity doping concentration of the preliminary buffer layer 180p may be in a range of approximately 1E17 cm⁻³ to 1E19 cm⁻³. The n-type impurity may include P, As, Sb, etc. In addition, the n-type impurity may be Se, S, Ti, Bi, etc.

Referring to FIG. 8F, the third mask (M1 of FIG. 8E) may be removed.

After removing the third mask Ml, the substrate 110 may be annealed so that the preliminary buffer layer (180p of FIG. 8E) may be diffused. As result, the portions of the preliminary buffer layer 180p may be laterally connected so that the buffer layer 180 may be formed.

The annealing process may be a laser annealing process or a thermal annealing process.

The preliminary buffer layer 180p may be laterally and perpendicularly diffused by the annealing process. In the buffer layer 180, parts formed on adjacent concave portions 115a may be connected to each other by the annealing process so that the buffer layer 180 may be formed (contiguous) over the total area of the substrate 110. In such arrangements, the buffer layer 180 may be defined to include the first region 180a that overlaps the concave portion 115a in the perpendicular direction and the second region 180b that does not overlap the concave portion 115b in the perpendicular direction. A width (may also be referred to a height) of the first region 180a in the perpendicular direction may be larger than a width (or height) of the second region 180b in the perpendicular direction. The impurity concentration of the buffer layer 180 may be increased and reduced (i.e., the buffer layer 180 may have fluctuations in the impurity concentration) in the direction where the plurality of concave portions 115a are separated from each other with reference to FIG. 2C.

Referring to FIG. 8G, a p-type impurity may be implanted into the second surface F2 of the substrate 110 and an internal wall of the concave portion 115a, so that a collector region 170 may be formed (defined). The collector region 170 may be conformally formed (defined) along the profile of the at least one uneven portion 115 to a predetermined thickness. The p-type impurity of the collector region 170 may include Al, B, In, K, etc. and the impurity doping concentration of the collector region 170 may be in a range of approximately 1E17 cm⁻³ to 1E19 cm⁻³.

Although not shown, a mask that fills the internal wall of the concave portion 115a may be formed and, then, the p-type impurity may be implanted into the second surface F2 of the substrate 110. Using such an approach, the collector region 170a may be formed only in the part of the substrate 110 that does not overlap the concave portion 115a in the perpendicular direction, so that the power semiconductor device 100c described with reference to FIG. 5 may be formed.

Referring to FIG. 1A again, a collector electrode 190 may be formed on the collector region 170. The collector electrode 190 may be conformally formed (disposed) along the profile of the at least one uneven portion 115.

The power semiconductor device 100 is completed by performing the above-described processes.

In general, when the buffer layer 180 is formed to a predetermined depth from the second surface F2 of the substrate, an impurity is implanted into the substrate by a high-energy ion implantation process using hydrogen so that the impurity may reach the desired position of the buffer layer 180. In such a case, the substrate 110 may be damaged by the high-energy ion implantation process or it may be difficult to control the position, thickness, and/or the impurity doping concentration of the buffer layer 180. However, by forming the preliminary buffer layer 180p in the concave portion 115a and then laterally diffusing the impurity of the preliminary buffer layer 180p by the subsequent annealing process to form the buffer layer 180, the position of the buffer layer 180 may be controlled by controlling the first depth D1 of the concave portion 115a. In addition, since the buffer layer 180 may be formed without using a high-energy ion implantation process, the impurity doping concentration of the buffer layer 180 may be readily controlled. Using the approaches described herein, the position, thickness, and/or doping concentration of the buffer layer 180 may be readily controlled by controlling the position of the concave portion 115a, and thus, a breakdown voltage of the power semiconductor device 100 may be improved and conduction loss and/or switching loss may be reduced.

It should be understood that the embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope of the following claims.

What is claimed is:

1. A power semiconductor device, comprising:
a substrate including a first surface and a second surface, the substrate having at least one uneven portion disposed on the second surface of the substrate;
a gate electrode disposed on the first surface of the substrate;
an emitter electrode disposed on the first surface of the substrate;
a collector region disposed on at least a part of the at least one uneven portion; and
a buffer layer disposed in the substrate.

2. The power semiconductor device of claim 1,
wherein the at least one uneven portion includes a concave portion that is recessed from the second surface of the substrate, and
wherein the buffer layer includes:
a first region that overlaps the concave portion in a perpendicular direction relative to the first surface of the substrate; and
a second region that does not overlap the concave portion in the perpendicular direction.

3. The power semiconductor device of claim 2, wherein the first region of the buffer layer has a first thickness, and the second region of the buffer layer has a second thickness that is less than the first thickness.

4. The power semiconductor device of claim 2, wherein an impurity concentration of the first region of the buffer layer is greater than an impurity concentration of the second region.

5. The power semiconductor device of claim 2, wherein the first region of the buffer layer is separated from the collector region by a first distance in the perpendicular direction and the second region of the buffer layer is separated from the collector region by a second distance in the perpendicular direction, the first distance being less than the second distance.

6. The power semiconductor device of claim 1, wherein at least a part of the buffer layer contacts at least a part of the collector region.

7. The power semiconductor device of claim 1, wherein the collector region includes a p-type impurity and the buffer layer includes an n-type impurity.

8. The power semiconductor device of claim 1, wherein the buffer layer is continuous on a surface parallel to the first surface of the substrate.

9. The power semiconductor device of claim 1, wherein an impurity concentration of the buffer layer varies in a perpendicular direction relative to the first surface of the substrate and varies in a parallel direction relative to the first surface of the substrate.

10. The power semiconductor device of claim 1, wherein the buffer layer defines a field stop region.

11. The power semiconductor device of claim 1, wherein the at least one uneven portion has a depth in a range of approximately 1 μm to 5 μm from the second surface of the substrate.

12. The power semiconductor device of claim 1, wherein the at least one uneven portion includes a plurality of concave portions that extend in a parallel direction relative to the first surface of the substrate.

13. The power semiconductor device of claim 1, wherein the at least one uneven portion comprises a plurality of concave portions separated from each other in a first direction and in a second direction, the first direction being parallel to the first surface of the substrate, the second direction being parallel to the first surface of the substrate and perpendicular to the first direction.

14. The power semiconductor device of claim 1, wherein the at least one uneven portion comprises a plurality of protrusions separated from each other in a first direction and in a second direction, the first direction being parallel to the first surface of the substrate, the second direction being parallel to the first surface of the substrate and perpendicular to the first direction.

15. The power semiconductor device of claim 1, further comprising a drift region disposed in the substrate and disposed between the buffer layer and the gate electrode.

16. The power semiconductor device of claim 1, wherein the collector region is disposed on the entire surface of the at least one uneven portion.

17. The power semiconductor device of claim 1, wherein the collector region is disposed on a part of a surface of the at least one uneven portion and does not overlap a concave surface of the at least one uneven portion.

18. The power semiconductor device of claim 1, wherein the buffer layer is spaced apart from the collector region in a perpendicular direction relative to the first surface of the substrate.

19. The power semiconductor device of claim 1, wherein:
the substrate includes:
a base region adjacent to the first surface and including a p-type impurity; and
an emitter region disposed in the base region and including an n-type impurity,
the gate electrode is configured to electrically control a part of the base region adjacent to the emitter region, and
the emitter electrode is electrically connected to the base region and the emitter region.

20. The power semiconductor device of claim 1, wherein the substrate includes a trench recessed from the first surface of the substrate to a predetermined depth, the gate electrode is disposed in the trench.

21. A method of manufacturing a power semiconductor device, the method comprising:
etching a second surface of a substrate including a first surface and the second surface to form at least one uneven portion;
implanting a first impurity into the second surface of the substrate to define a buffer layer; and
implanting a second impurity into the second surface of the substrate to define a collector region.

22. The method of claim 21, wherein the forming of the buffer layer includes:
implanting the first impurity into a concave surface of the at least one uneven portion; and
annealing the substrate to laterally diffuse the first impurity.

23. The method of claim 22, wherein the annealing the substrate includes at least one of laser annealing or thermal annealing.

24. The method of claim 21, wherein the at least one uneven portion has a depth in a range of approximately 1 μm to 5 μm from the second surface of the substrate.

25. The method of claim 21, wherein the forming of the at least one uneven portion includes forming a plurality of concave portions that extend in a first direction parallel to the second surface.

26. The method of claim 21, wherein the forming of the at least one uneven portion includes forming a plurality of concave portions separated from each other in a first direction and in a second direction, the first direction being parallel to the first surface of the substrate, the second direction being parallel to the first surface of the substrate and perpendicular to the first direction.

27. The method of claim 21, wherein the forming of the at least one uneven portion includes forming a plurality of protrusions separated from each other in a first direction and in a second direction, the first direction being parallel to the first surface of the substrate, the second direction being parallel to the first surface of the substrate and perpendicular to the first direction.

28. The method of claim 21, wherein the forming of the collector region includes forming the collector region on at least a part of the at least one uneven portion.
